(19) United States
(12) Patent Application Publication
(10) Pub. No.: US 2018/0059870 A1
(43) Pub. Date: Mar. 1, 2018

(54) ANALOG FRONT END WITH VARIABLE GAIN CONTROL FOR TOUCH APPLICATIONS

(71) Applicant: Apple Inc., Cupertino, CA (US)

(72) Inventor: Christoph H. KRAH, Cupertino, CA (US)

(21) Appl. No.: 15/674,232

(22) Filed: Aug. 10, 2017

Related U.S. Application Data
(60) Provisional application No. 62/382,199, filed on Aug. 31, 2016.

(51) Int. Cl. G06F 3/041; G06F 3/044; H03G 3/20; H03K 17/96; H03K 17/955

(52) U.S. Cl. CPC G06F 3/0418; G06F 3/044; H03G 3/20; H03K 2217/96074; H03K 17/955; G06F 2203/04108; H03K 17/962

(57) ABSTRACT

An analog front end (AFE) can be implemented with automatic variable gain control for self-capacitance based touch- and proximity-sensitive touch sensor panels or touch screens. The AFE can include a charge amplifier and an oversampled analog-to-digital converter (ADC). The AFE can also include multiple signal paths between the charge amplifier and the ADC. The variable gain control can monitor the output of the oversampled ADC and, based on the oversampled ADC output, automatically select one of the multiple signal paths. When the output of the ADC indicates a proximity condition (e.g., relatively small signal, relatively large noise headroom when compared with a touch condition), the automatically selected signal path can amplify the charge amplifier output. The bit resolution of the oversampled ADC in the AFE can be relaxed as a result of the variable gain control.

### CROSS-REFERENCE TO RELATED APPLICATIONS

This application claims benefit of U.S. Provisional Patent Application No. 62/382,199, filed Aug. 31, 2016, which is hereby incorporated by reference in its entirety.

### FIELD OF THE DISCLOSURE

This relates generally to analog front end designs for sensors and, more specifically, to an analog front end with variable gain control for proximity-sensitive and touch-sensitive sensors.

### BACKGROUND OF THE DISCLOSURE

Many types of input devices are presently available for performing operations in a computing system, such as buttons or keys, mice, trackballs, joysticks, touch sensor panels, touch screens and the like. Touch screens, in particular, are becoming increasingly popular because of their ease and versatility of operation as well as their declining price. Touch screens can include a touch sensor panel, which can be a clear panel with a touch-sensitive surface, and a display device such as a liquid crystal display (LCD) that can be positioned partially or fully behind the panel so that the touch-sensitive surface can cover at least a portion of the viewable area of the display device. Touch screens can allow a user to perform various functions by touching the touch sensor panel using a finger, stylus or other object at a location often dictated by a user interface (UI) being displayed by the display device. In general, touch screens can recognize a touch and the position of the touch on the touch sensor panel, and the computing system can then interpret the touch in accordance with the display appearing at the time of the touch, and thereafter can perform one or more actions based on the touch. In the case of some touch sensing systems, a physical touch on the display is not needed to detect a touch. For example, in some capacitive-type touch sensing systems, fringing electrical fields used to detect touch can extend beyond the surface of the display, and objects approaching near the surface may be detected near the surface without actually touching the surface.

Capacitive touch sensor panels can be formed by a matrix of substantially transparent or non-transparent conductive plates made of materials such as Indium Tin Oxide (ITO). It is due in part to their substantial transparency that capacitive touch sensor panels can be overlaid on a display to form a touch screen, as described above. Some touch screens can be formed by at least partially integrating touch sensing circuitry into a display pixel stack-up (i.e., the stacked material layers forming the display pixels).

### SUMMARY OF THE DISCLOSURE

This relates to an analog front end (AFE) with automatic variable gain control for self-capacitance based touch- and proximity-sensitive touch sensor panels or touch screens. The AFE can include a charge amplifier and an oversampled analog-to-digital converter (ADC). The AFE can also include multiple signal paths between the charge amplifier and the ADC. The variable gain control can monitor the output of the oversampled ADC and, based on the oversampled ADC output, automatically select one of the multiple signal paths. When the output of the ADC indicates a proximity condition (e.g., relatively small signal, relatively large noise headroom when compared with a touch condition), the automatically selected signal path can amplify the charge amplifier output. The bit resolution of the oversampled ADC in the AFE can be relaxed as a result of the variable gain control.

### BRIEF DESCRIPTION OF THE DRAWINGS

FIGS. 1A-1D illustrate an exemplary mobile telephone, an exemplary media player, an exemplary portable computing device, and an exemplary tablet computing device that can each include an exemplary analog front end according to examples of the disclosure.

FIG. 2 illustrates a block diagram of an exemplary computing system including a touch screen and an exemplary analog front end according to examples of the disclosure.

FIG. 3A illustrates an exemplary touch sensor circuit corresponding to a self-capacitance touch node and sensing circuit according to examples of the disclosure.

FIG. 3B illustrates an exemplary configuration in which common electrodes can form portions of touch sensing circuitry of a touch sensing system according to examples of the disclosure.

FIGS. 4A-4C illustrate exemplary interference budgets for touch and proximity signals according to examples of the disclosure.

FIG. 5 illustrates an exemplary block diagram including an analog front end (AFE) with variable gain control according to examples of the disclosure.

FIG. 6 illustrates an exemplary state diagram for variable gain control according to examples of the disclosure.

FIG. 7 illustrates an exemplary process for variable gain control for an analog front end according to examples of the disclosure.

### DETAILED DESCRIPTION

In the following description of examples, reference is made to the accompanying drawings which form a part hereof, and in which it is shown by way of illustration specific examples that can be practiced. It is to be understood that other examples can be used and structural changes can be made without departing from the scope of the disclosed examples.

This relates to an analog front end (AFE) with automatic variable gain control for self-capacitance based touch- and proximity-sensitive touch sensor panels or touch screens. The AFE can include a charge amplifier and an oversampled analog-to-digital converter (ADC). The AFE can also include multiple signal paths between the charge amplifier and the ADC. The variable gain control can monitor the output of the oversampled ADC and, based on the oversampled ADC output, automatically select one of the multiple signal paths. When the output of the ADC indicates a proximity condition (e.g., relatively small signal, relatively large noise headroom when compared with a touch condition), the automatically selected signal path can amplify the charge amplifier output. The bit resolution of the oversampled ADC in the AFE can be relaxed as a result of the variable gain control.

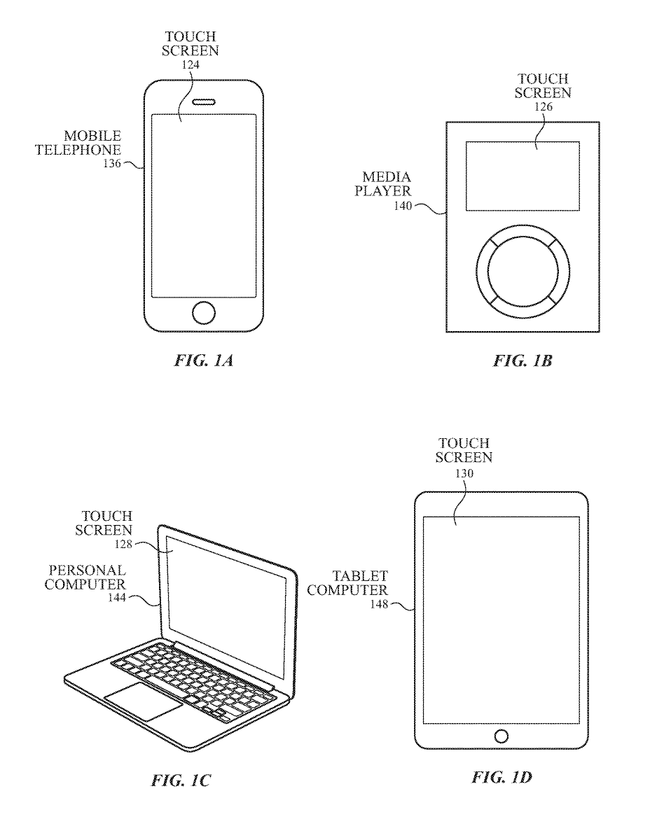

FIGS. 1A-1D show exemplary systems in which a touch screen and an analog front end according to examples of the disclosure may be implemented. FIG. 1A illustrates an exemplary mobile telephone 136 that includes a touch screen 124 and can include an analog front end according to examples of the disclosure. FIG. 1B illustrates an exemplary digital media player 140 that includes a touch screen 126 and can include an analog front end according to examples of the disclosure. FIG. 1C illustrates an exemplary portable computing device 144 that includes a touch screen 128 and can include an analog front end according to examples of the disclosure. FIG. 1D illustrates an exemplary tablet computing device 148 that includes a touch screen 130 and can include an analog front end according to examples of the disclosure. It is understood that the above touch screens and an analog front end according to examples of the disclosure can be implemented in other devices as well, including in wearable devices.

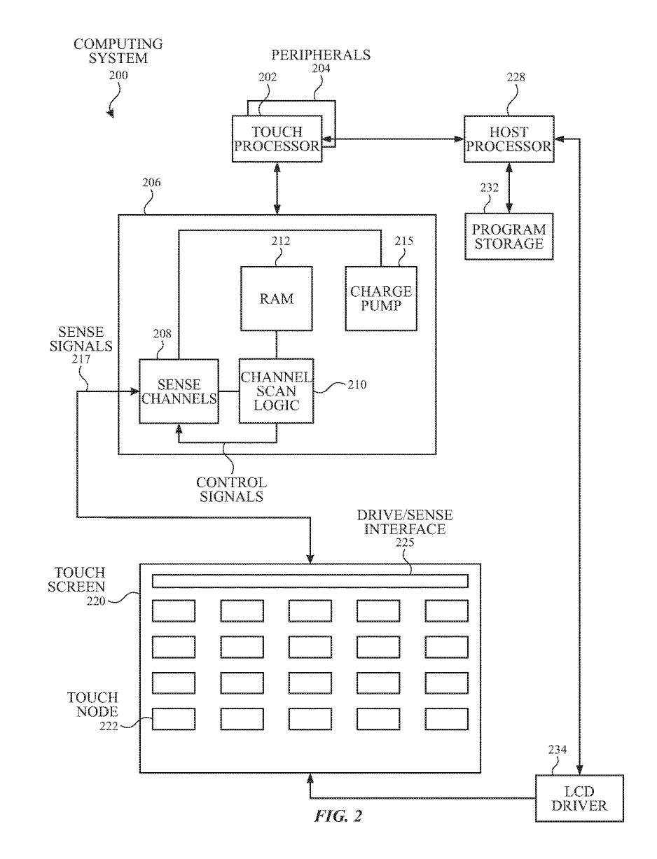

In some examples, touch screens 124, 126, 128 and 130 can be based on self-capacitance or mutual capacitance. A touch system can include a matrix of small plates of conductive material that can be referred to as a touch pixel, touch node, or a touch pixel electrode (as described below with reference to touch screen 220 in FIG. 2). For example, a touch screen can include a plurality of individual touch nodes, each touch node identifying or representing a unique location on the touch screen at which touch or proximity (i.e., a touch or proximity event) is to be sensed, and each touch node being electrically isolated from the other touch nodes in the touch screen/panel. Such a touch screen can be referred to as a pixelated touch screen. During self-capacitance operation of the pixelated touch screen, a touch node can be stimulated with an AC waveform, and the self-capacitance of the touch node can be measured. As an object approaches the touch node, the self-capacitance to ground of the touch node can change. This change in the self-capacitance of the touch node can be detected and measured by the touch sensing system to determine the positions of multiple objects when they touch, or come in proximity to, the touch screen. In some examples, the electrodes of a self-capacitance based touch system can be formed from rows and columns of conductive material, and changes in the self-capacitance to ground of the rows and columns can be detected, similar to above. In some examples, a touch screen can be multi-touch, single touch, projection scan, full-imaging multi-touch, capacitive touch, etc.

FIG. 2 illustrates a block diagram of an exemplary computing system 200 including a touch screen 220 and an exemplary analog front end according to examples of the disclosure. Computing system 200 can be included in, for example, mobile telephone 136, digital media player 140, portable computing device 144, tablet computing device 148, or any mobile or non-mobile computing device that includes a touch screen, including a wearable device. Computing system 200 can include a touch sensing system including one or more touch processors 202, peripherals 204, a touch controller 206, and touch sensing circuitry (described in more detail below). Peripherals 204 can include, but are not limited to, random access memory (RAM) or other types of memory or storage, watchdog timers and the like. Touch controller 206 can include, but is not limited to, one or more sense channels 208 and channel scan logic 210. Channel scan logic 210 can access RAM 212, autonomously read data from sense channels 208 and provide control for the sense channels. In addition, channel scan logic 210 can control sense channels 208 to generate stimulation signals at various frequencies and phases that can be selectively applied to the touch nodes of touch screen 220, as described in more detail below. The various scans performed by the touch controller can be selected and sequenced according to a scan plan. In some examples, touch controller 206, touch processor 202 and peripherals 204 can be integrated into a single application specific integrated circuit (ASIC), and in some examples can be integrated with touch screen 220 itself.

Touch screen 220 can be a self-capacitance touch screen, and can include touch sensing circuitry that can include a capacitive sensing medium having a plurality of touch nodes 222 (e.g., a pixelated touch screen). Touch nodes 222 can be coupled to sense channels 208 in touch controller 206, can be driven by stimulation signals from the sense channels through drive/sense interface 225, and can be sensed by the sense channels through the drive/sense interface as well, as described above for a self-capacitance operation. In some examples, sense channels 208 can include an analog front end (AFE) according to examples of the disclosure. Labeling the conductive plates used to detect touch (i.e., touch nodes 222) as “touch pixel” electrodes can be particularly useful when touch screen 220 is viewed as capturing an “image” of touch. In other words, after touch controller 206 has determined an amount of touch detected at each touch node 222 in touch screen 220, the pattern of touch nodes in the touch screen at which a touch occurred can be thought of as an “image” of touch (e.g., a pattern of fingers touching the touch screen).

Computing system 200 can also include a host processor 228 for receiving outputs from touch processor 202 and performing actions based on the outputs. For example, host processor 228 can be connected to program storage 232 and a display controller, such as an LCD driver 234. The LCD driver 234 can provide voltages on select (gate) lines to each pixel transistor and can provide data signals along data lines to these same transistors to control the pixel display image as described in more detail below. Host processor 228 can use LCD driver 234 to generate a display image on touch screen 220, such as a display image of a user interface (UI), and can use touch processor 202 and touch controller 206 to detect a touch on or near touch screen 220. The touch input can be used by computer programs stored in program storage 232 to perform actions that can include, but are not limited to, moving an object such as a cursor or pointer, scrolling or panning, adjusting control settings, opening a file or document, viewing a menu, making a selection, executing instructions, operating a peripheral device connected to the host device, answering a telephone call, placing a telephone call, terminating a telephone call, changing the volume or audio settings, storing information related to telephone communications such as addresses, frequently dialed numbers, received calls, missed calls, logging onto a computer or a computer network, permitting authorized individuals access to restricted areas of the computer or computer network, loading a user profile associated with a user's preferred arrangement of the computer desktop, permitting access to web content, launching a particular program, encrypting or decoding a message, and/or the like. Host processor 228 can also perform additional functions that may not be related to touch processing.

Note that one or more of the functions described herein, including the configuration and operation of electrodes and sense channels, can be performed by firmware stored in memory (e.g., one of the peripherals 204, RAM 212 in FIG. 2) and executed by touch processor 202, or stored in program storage 232 and executed by host processor 228. The firmware can also be stored and/or transported within any non-transitory computer-readable storage medium for use by or in connection with an instruction execution system, apparatus, or device, such as a computer-based system, processor-containing system, or other system that can fetch the instructions from the instruction execution system, apparatus, or device and execute the instructions. In the context of this document, a “non-transitory computer-readable storage medium” can be any medium (excluding signals) that can contain or store the program for use by or in connection with the instruction execution system, apparatus, or device. The computer-readable storage medium can include, but is not limited to, an electronic, magnetic, optical, electromagnetic, infrared, or semiconductor system, apparatus or device, a portable computer diskette (magnetic), a random access memory (RAM) (magnetic), a read-only memory (ROM) (magnetic), an erasable programmable read-only memory (EPROM) (magnetic), a portable optical disc such a CD, CD-R, CD-RW, DVD, DVD-R, or DVD-RW, or flash memory such as compact flash cards, secured digital cards, USB memory devices, memory sticks, and the like.

The firmware can also be propagated within any transport medium for use by or in connection with an instruction execution system, apparatus, or device, such as a computer-based system, processor-containing system, or other system that can fetch the instructions from the instruction execution system, apparatus, or device and execute the instructions. In the context of this document, a “transport medium” can be any medium that can communicate, propagate or transport the program for use by or in connection with the instruction execution system, apparatus, or device. The transport medium can include, but is not limited to, an electronic, magnetic, optical, electromagnetic or infrared wired or wireless propagation medium.

It is to be understood that computing system 200 is not limited to the components and configuration of FIG. 2, but can include other or additional components in multiple configurations according to various examples. Additionally, the components of computing system 200 can be included within a single device, or can be distributed between multiple devices.

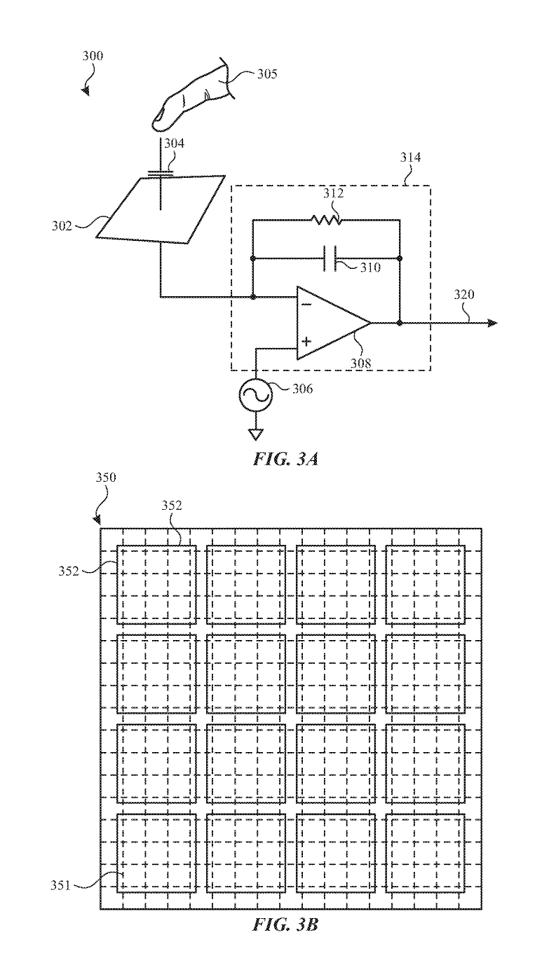

FIG. 3A illustrates an exemplary touch sensor circuit 300 corresponding to a self-capacitance touch node 302 and sensing circuit 314 according to examples of the disclosure. Touch node 302 can correspond to touch node 222. Touch node 302 can have an inherent self-capacitance to ground associated with it, and also an additional self-capacitance to ground that is formed when an object, such as finger 305, is in proximity to or touching the electrode. The total self-capacitance to ground of touch node 302 can be illustrated as capacitance 304. Touch node 302 can be coupled to sensing circuit 314 (which can correspond to part of sense channels 208). Sensing circuit 314 can include an operational amplifier 308, feedback resistor 312, feedback capacitor 310 and an input voltage source 306, although other configurations can be employed. For example, feedback resistor 312 can be replaced by a switched capacitor resistor in order to minimize any parasitic capacitance effect caused by a variable feedback resistor. Touch node 302 can be coupled to the inverting input of operational amplifier 308. An AC voltage source 306 (Vac) can be coupled to the non-inverting input of operational amplifier 308. Touch sensor circuit 300 can be configured to sense changes in the total self-capacitance 304 of the touch node 302 induced by a finger or object either touching or in proximity to the touch sensor panel. Output 320 can be used by a processor (e.g., touch controller 206) to determine the presence of a touch event, or the output can be inputted into a discrete logic network to determine the presence of a touch or proximity event. It is understood that a “touch event,” as used in this disclosure, encompasses a finger or object touching the touch sensor panel (i.e., being in physical contact with the touch sensor panel), as well as the finger or object being in proximity to, but not touching, the touch sensor panel. Touch sensor circuit 300 can represent the structure and/or operation of touch node self-capacitance sensing of the examples of the disclosure.

Although not shown in FIG. 2, in some examples, the self-capacitance touch screen can be operated in a bootstrapped mode (fully-bootstrapped or partially-bootstrapped). In self-capacitance based touch screens, any capacitance seen by a self-capacitance touch node can affect the total self-capacitance measured at that touch node, and can thus affect touch measurements at that touch node. Therefore, in some examples, it can be beneficial to “bootstrap” touch nodes of the touch screen during operation in order to reduce or cancel any unwanted stray capacitances and/or parasitic capacitances that may contribute to the total self-capacitance measured at a touch node. “Bootstrapping” touch nodes of the touch screen during operation can entail driving one or more portions of a touch screen with a voltage at the same frequency and phase as is used to drive and sense a touch node (as described above), so that capacitances that may exist between the touch node and the one or more portions of the touch screen can be effectively canceled. In one example fully-bootstrapped operating mode, each touch node in the touch screen can be driven at the same frequency/phase. In one example fully-bootstrapped operating mode, each touch node of a portion of touch screen (e.g., the top half, an upper-right quadrant, etc.) can be driven at the same frequency/phase. In one example partial-bootstrapped operating mode, three out of every four touch nodes can be driven at the same frequency/phase and the fourth out of every four touch nodes can be grounded (e.g., to improve touch detected of an otherwise ungrounded touch object). In some examples, the touch screen can also include a guard shield (e.g., below touch node 302), which can also be bootstrapped.

Referring back to FIG. 2, in some examples, touch screen 220 can be an integrated touch screen in which touch sensing circuit elements of the touch sensing system can be integrated into the display pixel stack-ups of a display. The circuit elements in touch screen 220 can include, for example, elements that can exist in LCD or other displays (e.g., OLED displays), such as one or more display pixel transistors (e.g., thin film transistors (TFTs)), gate lines, data lines, display pixel electrodes and common electrodes. In any given display pixel, a voltage between a display pixel electrode and a common electrode can control a luminance of the display pixel. The voltage on the display pixel electrode can be supplied by a data line through a display pixel transistor, which can be controlled by a gate line. It is noted that circuit elements are not limited to whole circuit components, such as a whole capacitor, a whole transistor, etc., but can include portions of circuitry, such as only one of the two plates of a parallel plate capacitor. FIG. 3B illustrates an example configuration in which common electrodes 352 can form portions of touch sensing circuitry of a touch sensing system according to examples of the disclosure. In some examples of this disclosure, the common electrodes can form touch nodes used to detect an image of touch on touch screen 350, as described above. Each common electrode 352 (i.e., touch node) can include a plurality of display pixels 351, and each display pixel 351 can include a portion of a common electrode 352, which can be a circuit element of the display system circuitry in the display pixel stack-up (i.e., the stacked material layers forming the display pixels) of the display pixels of some types of LCD or other displays that can operate as part of the display system to display a display image.

In the example shown in FIG. 3B, each common electrode 352 can serve as a multi-function circuit element that can operate as display circuitry of the display system of touch screen 350 and can also operate as touch sensing circuitry of the touch sensing system. In this example, each common electrode 352 can operate as a common electrode of the display circuitry of the touch screen 350, as described above, and can also operate as touch sensing circuitry of the touch screen. For example, a common electrode 352 can operate as a capacitive part of a touch node of the touch sensing circuitry during the touch sensing phase. Other circuit elements of touch screen 350 can form part of the touch sensing circuitry by, for example, switching electrical connections, etc. More specifically, in some examples, during the touch sensing phase, a gate line can be connected to a power supply, such as a charge pump, that can apply a voltage to maintain TFTs in display pixels included in a touch node in an “off” state. Stimulation signals can be applied to common electrode 352. Changes in the total self-capacitance of common electrode 352 can be sensed through an operational amplifier, as previously discussed. The change in the total self-capacitance of common electrode 352 can depend on the proximity of a touch object, such as a finger, to the common electrode. In this way, the measured change in total self-capacitance of common electrode 352 can provide an indication of touch on or near the touch screen.

In general, each of the touch sensing circuit elements may be either a multi-function circuit element that can form part of the touch sensing circuitry and can perform one or more other functions, such as forming part of the display circuitry, or may be a single-function circuit element that can operate as touch sensing circuitry only. Similarly, each of the display circuit elements may be either a multi-function circuit element that can operate as display circuitry and perform one or more other functions, such as operating as touch sensing circuitry, or may be a single-function circuit element that can operate as display circuitry only. Therefore, in some examples, some of the circuit elements in the display pixel stack-ups can be multi-function circuit elements and other circuit elements may be single-function circuit elements. In other examples, all of the circuit elements of the display pixel stack-ups may be single-function circuit elements.

In addition, although examples herein may describe the display circuitry as operating during a display phase, and describe the touch sensing circuitry as operating during a touch sensing phase, it should be understood that a display phase and a touch sensing phase may be operated at the same time, e.g., partially or completely overlap, or the display phase and touch sensing phase may operate at different times. Also, although examples herein describe certain circuit elements as being multi-function and other circuit elements as being single-function, it should be understood that the circuit elements are not limited to the particular functionality in other examples. In other words, a circuit element that is described in one example herein as a single-function circuit element may be configured as a multi-function circuit element in other examples, and vice versa.

The common electrodes 352 (i.e., touch nodes) and display pixels 351 of FIG. 3B are shown as rectangular or square regions on touch screen 350. However, it is understood that the common electrodes 352 and display pixels 351 are not limited to the shapes, orientations, and positions shown, but can include any suitable configurations according to examples of the disclosure.

While the discussion in this disclosure focuses on touch screens, it is understood that some or all of the examples of the disclosure can similarly be implemented in a touch sensor panel (i.e., a panel having touch sensing circuitry without display circuitry). For brevity, however, some of the examples of the disclosure have been, and will be, described in the context of a touch screen.

As described herein, the computing system can detect touch events from an object touching or in proximity to the touch screen. When an object enters a detection range of the touch screen, but remains at a distance from the touch screen, the changes in self-capacitance (touch/hover signal) can be orders of magnitude smaller than when an object touches the touch screen (e.g., 1-500 fF for a proximate object at a distance from the touch screen compared with 1-10 pF for an touching object). Resolving such small touch signals from proximate objects at a distance from the touch screen can require a much larger dynamic range for an analog-to-digital converter (ADC). The larger dynamic range of the ADC can result in the ADC consuming more power and circuit area. Thus, an ADC configured to sense both touching objects and proximate objects at a distance from the touch screen can, in some examples, require an ADC with a larger dynamic range relative to ADC requirements for a touch screen configured to sense touch without proximity sensing capability.

In some examples, rather than increasing the dynamic range and the complexity of the ADC, when detecting proximate objects at a distance from the touch screen the analog front end (AFE) can boost the signal output from the charge amplifier using a gain stage. By amplifying the signals output from the charge amplifier, unused noise headroom of the dynamic range of the charge amplifier can be traded off to reduce the dynamic range requirements for the ADC (fewer bits of resolution can be required).

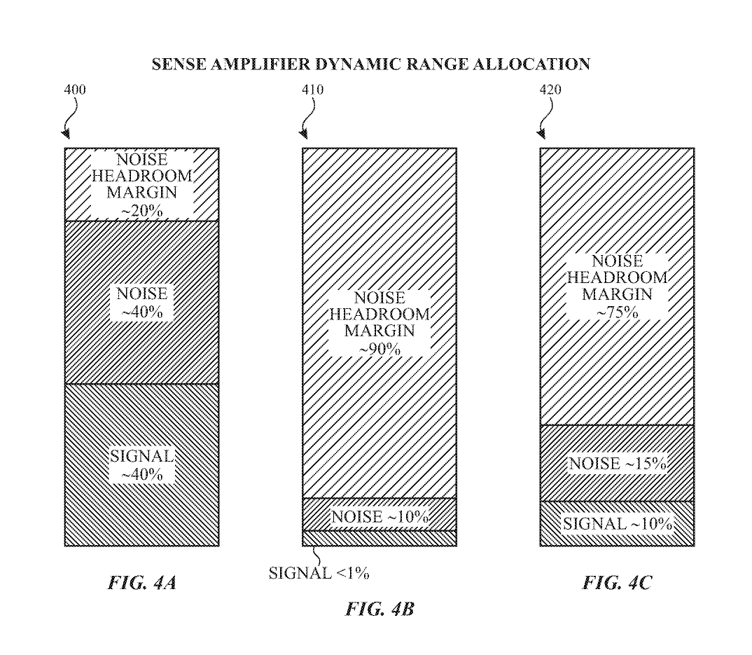

FIGS. 4A-4C illustrate exemplary interference budgets for touch and proximity signals according to examples of the disclosure. The exemplary interference budgets can correspond to a fully-bootstrapped AFE implementation, where the charge amplifier output signal level can be primarily a function of the finger to sensor capacitance. Dynamic range allocation 400 in FIG. 4A corresponds to an object such as a finger touching a touch screen. As discussed above, a touch signal from a touching finger can be measured in the pF range, and can consume approximately 40% of the dynamic range of the sense amplifier (e.g., corresponding to amplifier 308). Noise in the touch sensing system from one or more chargers (AC, wireless, etc.), from the display, and/or from one or more wireless communication systems (e.g., NFC), can consume approximately 40% of the dynamic range of the sense amplifier. The remaining 20% of dynamic range of the sense amplifier can be noise headroom to avoid saturation of the sense amplifier.

Dynamic range allocation 410 in FIG. 4B corresponds to an object such as a finger proximate to a touch screen at or near the maximum detection range for a proximate object. As discussed above, a touch signal from a proximate, but not touching finger (i.e., a proximity signal) can be measured in the fF range. When the finger is at or near the maximum detection range for proximate objects, the touch signal can consume less than 1% of the dynamic range of the sense amplifier (e.g., corresponding to amplifier 308). Noise in the touch sensing system from one or more chargers (AC, wireless, etc.), from the display, and/or from one or more wireless communication systems (e.g., NFC), can consume approximately 10% of the dynamic range of the sense amplifier. The noise in the touch sensing system can be smaller in the proximity case illustrated in FIG. 4B relative to the touch case of FIG. 4A because much of the noise coupling into the touch screen can be introduced by paths through the finger. The remaining approximately 90% of dynamic range of the sense amplifier can be noise headroom to avoid saturation of the sense amplifier. Given that for the touch case illustrated in FIG. 4A a noise margin of approximately 20% can be used, a large portion of the noise margin in FIG. 4B can be unused (e.g., wasted). Instead, some of this excess noise margin can be traded off by amplifying the touch signal from a proximate object at a distance from the touch screen, thereby providing for relaxation in the bit resolution of the ADC in such cases. For example, a gain of approximately 10 can be applied to the signal corresponding to the proximate but not touching object and the ADC dynamic range can be correspondingly relaxed.

Dynamic range allocation 420 in FIG. 4C corresponds to an object such as a finger proximate to, but not in contact with a touch screen, but at a distance closer to the surface of the touch screen than the case illustrated in FIG. 4B. At this closer distance, the touch signal can consume approximately 10% of the dynamic range of the sense amplifier (e.g., corresponding to amplifier 308). Noise in the touch sensing system from one or more chargers (AC, wireless, etc.), from the display, and/or from one or more wireless communication systems (e.g., NFC), can consume approximately 15% of the dynamic range of the sense amplifier. The noise in the touch sensing system can be larger in the proximity case illustrated in FIG. 4C relative to the proximity case of FIG. 4B, because the relative proximity of the finger (smaller distance between the finger and touch screen) provides for more coupling into the touch screen via the finger. The remaining approximately 75% of dynamic range of the sense amplifier can be noise headroom to avoid saturation of the sense amplifier. The unused noise margin in FIG. 4C can be traded off by amplifying the touch signal from a proximate object (e.g., by approximately 4), thereby providing for a corresponding relaxation in the resolution of the ADC.

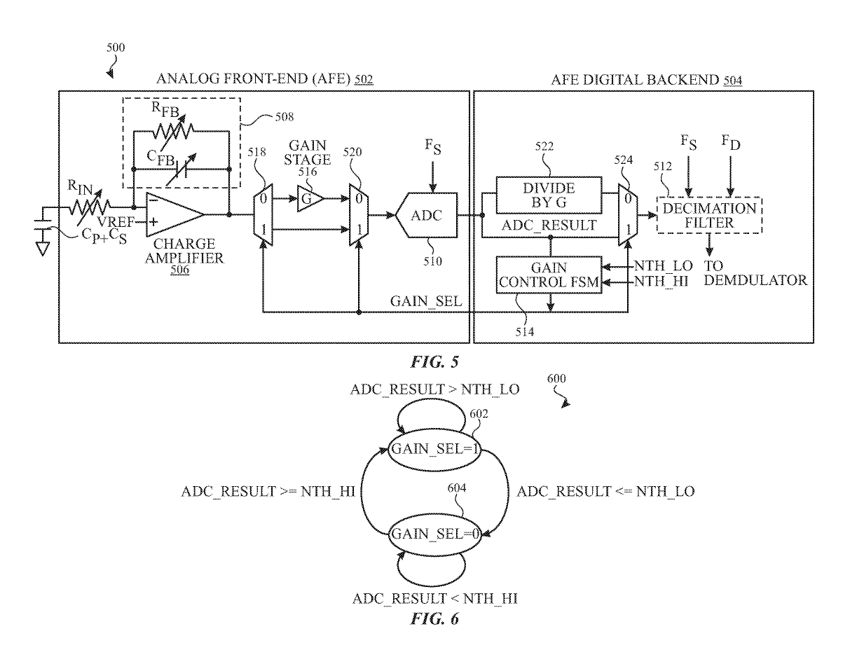

As discussed above, for a proximity condition, the sense amplifier output can be amplified to allow for a power- and area-saving ADC implementation. However, the same amplification applied to the sense amplifier output in a touch condition can result in saturation of the sense amplifier. A dynamic AFE gain control can be used to automatically adjust the gain appropriately for both touch and proximity situations. FIG. 5 illustrates an exemplary block diagram 500 including an analog front end (AFE) with variable gain control according to examples of the disclosure. Block diagram 500 can correspond to at least a part of receive channel 208. As illustrated in FIG. 5, block diagram 500 can include AFE 502 and AFE digital backend 504. AFE 502 can include a front end amplifier, charge amplifier 506, with a feedback network 508 including an adjustable feedback resistor and an adjustable feedback capacitor, for example (e.g., corresponding to operational amplifier 308, feedback capacitor 310 and feedback resistor 312). Additionally, AFE 502 can include an adjustable input resistance, which, together with the characteristic capacitance of the touch node (parasitic capacitance Cp and sense capacitance Cs), can form a first-order, low-pass filter, which can be used as part of an anti-aliasing filter and can also provide additional noise filtering.

AFE 502 can also include an ADC 510. ADC 510 can be implemented with a successive-approximation register ADC (SAR ADC), a sigma-delta ADC, or any other suitable ADC. In some examples, the ADC 510 can include a resistor network (R-to-R) or capacitor (C-to-C) network (not shown) that can be used to convert the analog input into a digital output. As described herein, reducing the number of bits of ADC 510 for measuring self-capacitance signals corresponding to proximate, but not touching objects can reduce the power and area requirements of the ADC. For example, when using a capacitor network for the ADC, the number of capacitors can be reduced by a factor of 2^{b}, where b can correspond to the number of bits of reduction in resolution. This reduction in the number of capacitors can reduce area and power (corresponding to the reduced dynamic charging currents when fewer capacitors are used).

In some examples, ADC 510 can accept a single ended input. In some examples, ADC 510 can accept a differential input. Although not shown, it should be understood that a single-ended to differential conversion circuit can be added between charge amplifier 506 and ADC 510.

ADC 510 can be oversampled such that multiple samples can be generated by the ADC once the output of charge amplifier 506 settles. Before the output of charge amplifier 506 settles, ADC 510 can optionally be powered down or the ADC output can be discarded or ignored. As illustrated in FIG. 5, ADC 510 can sample and convert inputs at a sampling rate, Fs, where the sampling rate can be considered oversampled because multiple samples rather than a single sample can be generated when the amplifier output transitions and settles. In some examples, the oversampling clock can operate at a frequency in a range between 24 MHz and 144 MHz. In some examples, the oversampling clock can operate at a frequency in a range between 50 MHz and 100 MHz.

Optionally, the oversampled output of ADC 510 can be decimated by decimation filter 512 in AFE digital backend 504. As illustrated, decimation filter 512 can receive both the oversampled sampling clock and a decimation clock. Decimating the ADC output can reduce the sampling rate of the signal (down-sampling) and provide anti-aliasing filtering. The filtering can add additional bits of resolution without requiring complexity (e.g., increased bit resolution) at the ADC. The reduction in the sampling rate can also filter out high frequency transients introduced by switching signal paths (e.g., by switches) of the variable gain control described herein.

Unlike conventional AFEs that provide one signal path coupling the output of the charge amplifier to the ADC, AFE 502 can include multiple signal paths between charge amplifier 506 and ADC 510, thereby providing a variable gain control. Transitioning between different signal paths rather than changing the gain of a single signal path in the AFE can provide responsive variable gain control for the oversampled ADC and in the time frame necessary to avoid saturation of the AFE. For example, FIG. 5 illustrates a first signal path including gain stage 516 configured to amplify the output of the charge amplifier by a gain greater than unity, and a second signal path to bypass the gain stage (e.g., providing no additional gain). The gain of gain stage 516 can be a function of the maximum interference budget for AFE 502. For example, as discussed above with respect to FIGS. 4B and 4C, the gain of the first path can be 10 or 4 (i.e., occupying no more than the full dynamic range allocation). In some cases the gain can be selected such that a threshold amount of noise headroom can remain after the gain (i.e., occupying less than the full dynamic range). In some cases, the gain of gain stage 516 can be a function of the size of the touch screen. Larger touch screens can be more bandwidth limited and therefore have smaller noise margins and correspondingly smaller gains for gain stage 516, whereas smaller touch screens can have greater noise margins and therefore may have sufficient headroom for a larger gain for gain stage 516. Charge amplifier 506 can be coupled to ADC 510 by either the first or second signal path via switches, such as multiplexors (MUXs) 518 and 520, for example. Control for MUXs 518 and 520 is discussed in more detail below.

In additional to adjusting the coupling between charge amplifier 506 and ADC 510, the AFE digital backend 504 can include multiple signal paths between the output of the ADC 510 and decimation filter 512. For example, a first path can include a scaling block 522 to divide by the inverse of the gain of the first path between the charge amplifier 506 and ADC 510, to undo the gain provided to the touch signals (when a proximity signal is detected) so as to maintain the same ADC output magnitude regardless of the gain. A second path can bypass the division (or divide by unity) when a touch signal is detected). Output of ADC 510 can be coupled to decimation filter 512 by either the first or second signal path via a switch, such as MUX 524, for example. Control for MUX 524 is discussed in more detail below.

The variable gain control for the AFE can be automatically adjusted based on the ADC output and one or more thresholds. AFE digital backend 504 can include a finite state machine 514 (e.g., implemented by hardware, firmware, and/or software) to generate a control signal (“GAIN_SEL”) for MUXs 518, 520 and 524 based on the output of ADC 510. As illustrated in FIG. 5, when GAIN_SEL is 0, charge amplifier 506 can be coupled to ADC 510 via the gain stage 516, and the output of ADC 510 can be divided (e.g., by scaling block 522) by the gain applied by gain stage 516 before being passed to decimator filter 512. When GAIN_SEL is 1, charge amplifier 506 can be coupled to ADC 510, bypassing gain stage 516, and the output of ADC 510 can be passed to decimator filter 512.

It is to be understood that block diagram 500 is not limited to the components and configuration of FIG. 5, but can include other or additional components in multiple configurations according to various examples. Additionally, the components of block diagram 500 can be included within a single device, or can be distributed between multiple devices.

Although variable gain control is implemented in the illustration of FIG. 5 with multiple fixed gain paths between charge amplifier 506 and ADC 510, it should be understood that, additionally or alternatively, the gain of charge amplifier 506 can be adjusted (e.g., via adjustment of variable resistor and capacitor in the feedback network 508) or the gain of gain stage 516 can be adjusted (e.g., between scan steps). The adjustment of the gain of the charge amplifier 506 and/or gain stage 516 can be a function on the interference levels measured at the ADC output. However, adjustments to the gain of these amplifiers may be insufficient to meet speed requirements of the oversampling ADC. In some examples, the gain of these amplifiers can be adjusted between scans or between scan steps, rather than adjusted on an ADC sample basis.

FIG. 6 illustrates an exemplary state diagram 600 for variable gain control according to examples of the disclosure. State diagram 600 in FIG. 6 can be implemented in finite state machine 514. Although two thresholds are included in state diagram 600 of FIG. 6 to provide hysteresis in the variable gain control, in some examples, a single transition threshold or additional thresholds can be implemented. In a first state 602 (e.g., GAIN_SEL=1), a state transition to the second state 604 (e.g., GAIN_SEL=0) can be triggered when the ADC output result is at or below the first threshold. The first threshold (NTH_LO) can correspond with a relatively low signal and noise/interference (e.g., 20-40% of the dynamic allocation). In other words, when there is sufficient noise headroom (e.g., corresponding to a proximity condition), state machine 600 can transition to the second state 604 to maintain high fidelity measurements for proximity without requiring a more costly ADC (e.g., in terms of power and area). If the ADC output is greater than the first threshold (NTH_LO), state machine 600 can remain in first state 602. In a second state 604 (e.g., GAIN_SEL=0), a state transition to the first state 602 (e.g., GAIN_SEL=1) can be triggered when the ADC output result is at or above the second threshold. The second threshold (NTH_HI) can correspond with a relatively large signal and noise/interference (e.g., 25-50% of the dynamic allocation). In other words, when there is no longer sufficient noise headroom (e.g., corresponding to a touch condition), state machine 600 can transition to the first state 602 to avoid saturation of the AFE. If the ADC output is less than the second threshold (NTH_HI), state machine 600 can remain in the second state 604.

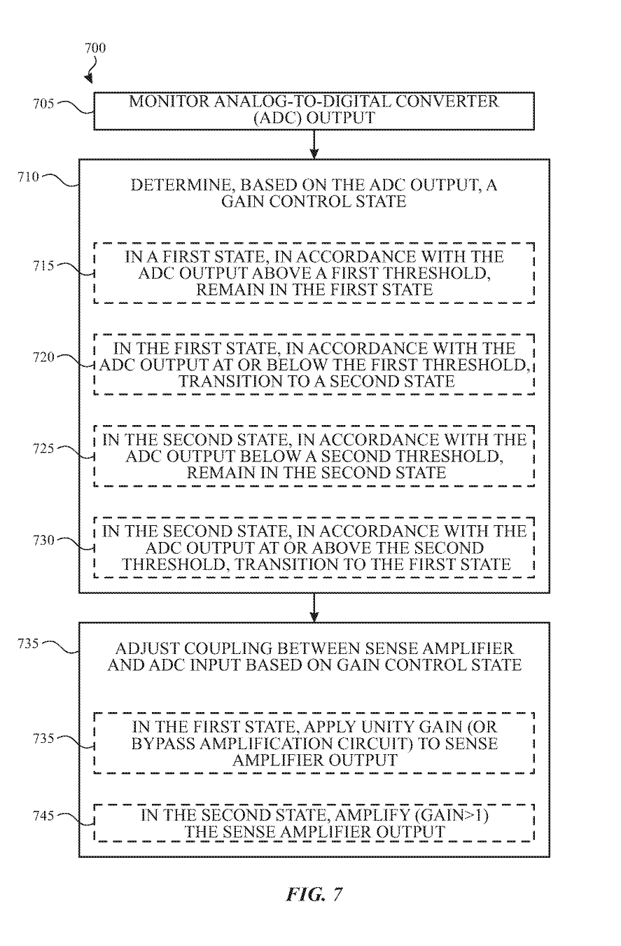

FIG. 7 illustrates an exemplary process 700 for variable gain control for an analog front end according to examples of the disclosure. At 705, the system (e.g., finite state machine 514) can monitor the output of the ADC. The system can determine, at 710, a gain control state for the variable gain control. In a first state (e.g., touch state), in accordance with the ADC output above a first threshold, the system can remain in the first state (715). In the first state, in accordance with the ADC output at or below the first threshold, the system can transition to a second state (e.g., proximity state) (720). In the second state, in accordance with the ADC output below a second threshold, they system can remain in the second state (725). In the second state, in accordance with the ADC output at or above the second threshold, transition to the first state (730).

At 735, based on the gain control state, the system can adjust coupling between the sense amplifier (e.g., charge amplifier 506) and an input of the ADC (e.g., ADC 510). In the first state (touch state), a unity gain can be applied to the sense amplifier output before the ADC input (or the gain stage can be bypassed) (740). In the second state (proximity state), a gain greater than unity can be applied to the sense amplifier output before the ADC (745). As discussed herein, in the second state the ADC output can be divided to reverse the gain provided by the gain stage before decimation (e.g., by scaling block 522).

Although the first state may be referred to as a touch state and the second state may be referred to as a proximity state, some proximate objects within a threshold distance from but not contacting the touch-sensitive surface (or indirectly contacting the touch sensitive surface by way of a non-conductive intermediary) may still be detected in the first state (and gain can be applied according to the first state) so long as the signal remains large enough to avoid triggering a transition from the first state to the second state. Proximate objects outside the threshold distance from the touch-sensitive surface (but within the detection range of the touch sensitive surface) can have a small enough detected signal to trigger a transition to the second state. The threshold(s) (e.g., NTH_HI and NTH_LO) can be used to set the boundaries between the first and second states.

Referring back to FIG. 5, although variable gain control is illustrated with two signal paths, a first path with gain stage 516 and a second path without a gain stage, in some examples, the second path can include a unity gain stage. In some examples, the second path can also include a gain stage with a gain different than unity. In such a case, rather than dividing the ADC output by the gain of gain stage 516 at scaling block 522, the ADC output can be divided by the gain of gain stage 516 and multiplied by the gain of the additional gain stage in the second path.

Additionally, although two variable gain control signal paths are shown in FIG. 5, more than two signal paths can be implemented. For example, the variable gain control AFE can be implemented with three signal paths: one with unity gain, one with a gain G₁ and one with a gain G₂, where G2>G1>1. Unity gain can be applied, for example, when noise margin is relatively small (e.g., corresponding to a finger touching the touch screen). When the noise margin is relatively moderate (e.g., corresponding to a finger within a first distance from the touch screen without touching the touch screen), gain G₁ can be applied. When the noise margin is relatively large (e.g., corresponding to a finger outside the first distance from the touch screen), gain G₂ can be applied. Three signal paths can also be included between the output of the ADC and the decimator to account for the variable gain (e.g., divide by 1, G₁, and G₂, respectively. The state machine can be updated accordingly to account for the additional states and transitions (including or excluding hysteresis).

Additionally, although finite state machine 514 illustrated in FIG. 5 transitions the gain control state based on the output directly from the ADC, in other examples, the output from decimation filter 512 can be used instead. The output of decimation filter 512 can include fewer transient components (e.g., introduced by the switching of MUXs 518 and 520), but because its output transitions slower than the sampling frequency of ADC 510, the variable gain control can be less responsive to changes in the touch signal. Additionally, although decimation filter 512 is illustrated in FIG. 5 as receiving the output of MUX 524, in some examples, decimation filter 512 can be coupled to the output of ADC 510 and subsequently the output of the decimation filter can be passed to either a first path or a second path to MUX 524.

Therefore, according to the above, some examples of the disclosure are directed to a sense channel. The sense channel can comprise: a first amplifier configurable to be coupled to a touch node and configured to measure a self-capacitance of the touch node; an analog-to-digital converter (ADC); and processing circuitry. The processing circuitry can be capable of: monitoring an output of the ADC; determining a gain control state from a first gain control state corresponding to an object touching a touch sensitive surface and a second gain control state corresponding to the object proximate to, but not touching the touch sensitive surface based on the output of the ADC; and adjusting a coupling between the first amplifier and an input of the ADC according to the gain control state. Additionally or alternatively to one or more of the examples disclosed above, in some examples, adjusting the coupling between the first amplifier and the input of the ADC can comprise: coupling, in a first gain control state, an output of the first amplifier to the input of the ADC via a first signal path; and coupling, in a second gain control state, the output of the first amplifier to the input of the ADC via a second signal path. The second signal path can be different than the first signal path. An amplitude of the output of the first amplifier can be equal to an amplitude of the input of the ADC when coupling via the first signal path. The second signal path can include a second amplifier configured to increase the amplitude of the input of the ADC relative to the amplitude of the output of the first amplifier. Additionally or alternatively to one or more of the examples disclosed above, in some examples, determining the gain control state can comprise: transitioning from a first gain control state to a second gain control state when the output of the ADC is at or below a first threshold; remaining in the first gain control state when the output of the ADC is above the first threshold; transitioning from the second gain control state to the first gain control state when the output of the ADC is at or above a second threshold; and remaining in the second gain control state when the output of the ADC is below the second threshold. Additionally or alternatively to one or more of the examples disclosed above, in some examples, the first threshold and second threshold can be different and can correspond to a dynamic range of the input of the ADC. Additionally or alternatively to one or more of the examples disclosed above, in some examples, the sense channel can further comprise: a decimation filter. The processing circuitry can be configured to adjust a coupling between the output of the ADC and the decimation filter according to the gain control state. Additionally or alternatively to one or more of the examples disclosed above, in some examples, adjusting the coupling between the output of the ADC and the decimation filter can comprise: coupling, in a first gain control state, the output of the ADC to the decimation filter via a first signal path; and coupling, in a second gain control state, the output of the ADC to the decimation filter via a second signal path. The second signal path can be different than the first signal path. The output of the ADC can be equal to an input of the decimation filter when coupling via the first signal path. The second signal path can be configured to scale the output of the ADC to decrease the input of the decimation filter relative to the output of the ADC. Additionally or alternatively to one or more of the examples disclosed above, in some examples, the sense channel can further comprise a plurality of switches. The coupling between the first amplifier and the input of the ADC can be adjusted via the plurality of switches. The processing circuitry can be further capable of generating a control signal to operate the plurality of switches. Additionally or alternatively to one or more of the examples disclosed above, in some examples, the sense channel can further comprise a plurality of selectable signal paths between the first amplifier and the input of the ADC. The processing circuitry is further capable of selecting one of the plurality of selectable signal paths to provide the output of the first amplifier to the input of the ADC. Additionally or alternatively to one or more of the examples disclosed above, in some examples, the processing circuitry can comprise a finite state machine. Additionally or alternatively to one or more of the examples disclosed above, in some examples, the ADC can be configured to accept a differential input. The sense channel can further comprise a single-ended to differential conversion circuit coupled between the first amplifier and the ADC. Additionally or alternatively to one or more of the examples disclosed above, in some examples, the ADC can b a successive approximation ADC.

Some examples of the disclosure are directed to a method. The method can comprise: monitoring an output of an oversampled analog-to-digital converter (ADC); determining a gain control state based on the output of the ADC; and adjusting a coupling between a charge amplifier and an input of the ADC according to the gain control state. Additionally or alternatively to one or more of the examples disclosed above, in some examples, adjusting the coupling between the charge amplifier and the input of the ADC can comprise: coupling, in a first gain control state, an output of the charge amplifier to the input of the ADC via a first signal path; and coupling, in a second gain control state, the output of the charge amplifier to the input of the ADC via a second signal path. The second signal path can be different than the first signal path. An amplitude of the output of the charge amplifier can be equal to an amplitude of the input of the ADC when coupling via the first signal path. The second signal path can include an amplifier configured to increase the amplitude of the input of the ADC relative to the amplitude of the output of the charge amplifier. Additionally or alternatively to one or more of the examples disclosed above, in some examples, determining the gain control state can comprise: transitioning from a first gain control state to a second gain control state when the output of the ADC is at or below a first threshold; remaining in the first gain control state when the output of the ADC is above the first threshold; transitioning from the second gain control state to the first gain control state when the output of the ADC is at or above a second threshold; and remaining in the second gain control state when the output of the ADC is below the second threshold. Additionally or alternatively to one or more of the examples disclosed above, in some examples, the method can further comprise adjusting a coupling between the output of the ADC and a decimation filter according to the gain control state. Additionally or alternatively to one or more of the examples disclosed above, in some examples, adjusting the coupling between the output of the ADC and the decimation filter can comprise: coupling, in a first gain control state, the output of the ADC to the decimation filter via a first signal path; and coupling, in a second gain control state, the output of the ADC to the decimation filter via a second signal path. The second signal path can be different than the first signal path. The output of the ADC can be equal to an input of the decimation filter when coupling via the first input path. The second signal path can be configured to scale the output of the ADC to decrease the input of the decimation filter relative to the output of the ADC. Some examples of the disclosure are directed to a non-transitory computer-readable medium including instructions, which when executed by one or more processors, cause the one or more processors to perform any of the above methods. Some examples of the disclosure are directed to an apparatus comprising: one or more processors; and a non-transitory computer-readable medium including instructions, which when executed by the one or more processors, cause the one or more processors to perform any of the above methods.

Some examples of the disclosure are directed to a sense channel. The sense channel can comprise: a first amplifier configurable to be coupled to a touch node and configured to measure a self-capacitance of the touch node; a second amplifier coupled to the first amplifier; an analog-to-digital converter (ADC) coupled to the second amplifier; and processing circuitry capable of: monitoring an output of the ADC; determining a gain control state based on the output of the ADC; and adjusting an amount of gain of the second amplifier according to the gain control state. Additionally or alternatively to one or more of the examples disclosed above, in some examples, the amount of gain can be adjusted between scan steps. Additionally or alternatively to one or more of the examples disclosed above, in some examples, the amount of gain can be adjusted between samples within a scan step.

Some examples of the disclosure are directed to a sense channel. The sense channel can comprise: a first amplifier configurable to be coupled to a touch node and configured to measure a self-capacitance of the touch node; a configurable gain circuit coupled to the first amplifier and configured to amplify an output of the first amplifier based on a selected gain of the configurable gain circuit; an analog-to-digital converter (ADC) coupled to the adjustable gain circuit; and processing circuitry capable of: monitoring an output of the ADC; determining a gain control state based on the output of the ADC; and select the selected gain according to the gain control state. Additionally or alternatively to one or more of the examples disclosed above, in some examples, the selected gain of the configurable gain circuit can be selected between scan steps. Additionally or alternatively to one or more of the examples disclosed above, in some examples, the selected gain of the configurable gain circuit can be selected between samples within a scan step. Additionally or alternatively to one or more of the examples disclosed above, in some examples, the configurable gain circuit can comprise a plurality of signal paths. Selecting the selected gain can comprise activating one of the plurality of signal paths. Additionally or alternatively to one or more of the examples disclosed above, in some examples, the configurable gain circuit can comprise an adjustable gain amplifier. Selecting the selected gain can comprise adjusting an amount of gain of the adjustable gain amplifier.

Some examples of the disclosure are directed to a sense channel. The sense channel can comprise: an amplifier configurable to be coupled to a touch node and configured to measure a self-capacitance of the touch node; an analog-to-digital converter (ADC) coupled to the amplifier; and processing circuitry capable of: monitoring an output of the ADC; determining a gain control state based on the output of the ADC; and adjusting an amount of gain of the amplifier according to the gain control state. Additionally or alternatively to one or more of the examples disclosed above, in some examples, the amount of gain can be adjusted between scan steps. Additionally or alternatively to one or more of the examples disclosed above, in some examples, the amount of gain can be adjusted between samples within a scan step.

Although the disclosed examples have been fully described with reference to the accompanying drawings, it is to be noted that various changes and modifications will become apparent to those skilled in the art. Such changes and modifications are to be understood as being included within the scope of the disclosed examples as defined by the appended claims.

1. A sense channel comprising:
a first amplifier configurable to be coupled to a touch node and configured to measure a self-capacitance of the touch node;
an analog-to-digital converter (ADC); and
processing circuitry capable of:
monitoring an output of the ADC;
determining a gain control state from a first gain control state corresponding to an object touching a touch sensitive surface and a second gain control state corresponding to the object proximate to, but not touching the touch sensitive surface based on the output of the ADC; and
adjusting a coupling between the first amplifier and an input of the ADC according to the gain control state.

2. The sense channel of claim 1, wherein adjusting the coupling between the first amplifier and the input of the ADC comprises:
coupling, in the first gain control state, an output of the first amplifier to the input of the ADC via a first signal path, wherein an amplitude of the output of the first amplifier is equal to an amplitude of the input of the ADC; and
coupling, in the second gain control state, the output of the first amplifier to the input of the ADC via a second signal path, wherein the second signal path is different than the first signal path and wherein the second signal path includes a second amplifier configured to increase the amplitude of the input of the ADC relative to the amplitude of the output of the first amplifier.

3. The sense channel of claim 1, wherein determining the gain control state comprises:
transitioning from the first gain control state to the second gain control state when the output of the ADC is at or below a first threshold;
remaining in the first gain control state when the output of the ADC is above the first threshold;
transitioning from the second gain control state to the first gain control state when the output of the ADC is at or above a second threshold; and
remaining in the second gain control state when the output of the ADC is below the second threshold.

4. The sense channel of claim 3, wherein the first threshold and second threshold are different and correspond to a dynamic range of the input of the ADC.

5. The sense channel of claim 1, further comprising:
a decimation filter;
wherein the processing circuitry is configured to adjust a coupling between the output of the ADC and the decimation filter according to the gain control state.

6. The sense channel of claim 5, wherein adjusting the coupling between the output of the ADC and the decimation filter comprises:
coupling, in the first gain control state, the output of the ADC to the decimation filter via a first signal path, wherein the output of the ADC is equal to an input of the decimation filter; and
coupling, in the second gain control state, the output of the ADC to the decimation filter via a second signal path, wherein the second signal path is different than the first signal path and wherein the second signal path is configured to scale the output of the ADC to decrease the input of the decimation filter relative to the output of the ADC.

7. The sense channel of claim 1, further comprising:
a plurality of switches, wherein the coupling between the first amplifier and the input of the ADC is adjusted via the plurality of switches; and
wherein the processing circuitry is further capable of generating a control signal to operate the plurality of switches.

8. The sense channel of claim 1, further comprising:
a plurality of selectable signal paths between the first amplifier and the input of the ADC; and
wherein the processing circuitry is further capable of selecting one of the plurality of selectable signal paths to provide the output of the first amplifier to the input of the ADC.

9. The sense channel of claim 1, wherein the processing circuitry comprises a finite state machine.

10. The sense channel of claim 1, wherein the ADC is configured to accept a differential input; and
wherein the sense channel further comprises a single-ended to differential conversion circuit coupled between the first amplifier and the ADC.

11. The sense channel of claim 1, wherein the ADC is a successive approximation ADC.

12. A method comprising:
monitoring an output of an oversampled analog-to-digital converter (ADC);
determining a gain control state based on the output of the ADC; and
adjusting a coupling between a charge amplifier and an input of the ADC according to the gain control state.

13. The method of claim 12, wherein adjusting the coupling between the charge amplifier and the input of the ADC comprises:
coupling, in the first gain control state, an output of the charge amplifier to the input of the ADC via a first signal path, wherein an amplitude of the output of the charge amplifier is equal to an amplitude of the input of the ADC; and
coupling, in the second gain control state, the output of the charge amplifier to the input of the ADC via a second signal path, wherein the second signal path is different than the first signal path and wherein the second signal path includes an amplifier configured to increase the amplitude of the input of the ADC relative to the amplitude of the output of the charge amplifier.

14. The method of claim 12, wherein determining the gain control state comprises:
transitioning from the first gain control state to the second gain control state when the output of the ADC is at or below a first threshold;
remaining in the first gain control state when the output of the ADC is above the first threshold;
transitioning from the second gain control state to the first gain control state when the output of the ADC is at or above a second threshold; and
remaining in the second gain control state when the output of the ADC is below the second threshold.

15. The method of claim 12, further comprising:
adjusting a coupling between the output of the ADC and a decimation filter according to the gain control state.

16. The method of claim 15, wherein adjusting the coupling between the output of the ADC and the decimation filter comprises:
coupling, in the first gain control state, the output of the ADC to the decimation filter via a first signal path, wherein the output of the ADC is equal to an input of the decimation filter; and
coupling, in the second gain control state, the output of the ADC to the decimation filter via a second signal path, wherein the second signal path is different than the first signal path and wherein the second signal path is configured to scale the output of the ADC to decrease the input of the decimation filter relative to the output of the ADC.

17. A non-transitory computer readable storage medium including instructions, that when executed by one or more processors, cause the one or more processors to perform a method, the comprising:
monitoring an output of an oversampled analog-to-digital converter (ADC);
determining a gain control state based on the output of the ADC; and
adjusting a coupling between a charge amplifier and an input of the ADC according to the gain control state.

18. The non-transitory computer readable storage medium of claim 17, wherein adjusting the coupling between the charge amplifier and the input of the ADC comprises:
coupling, in the first gain control state, an output of the charge amplifier to the input of the ADC via a first signal path, wherein an amplitude of the output of the charge amplifier is equal to an amplitude of the input of the ADC; and
coupling, in the second gain control state, the output of the charge amplifier to the input of the ADC via a second signal path, wherein the second signal path is different than the first signal path and wherein the second signal path includes an amplifier configured to increase the amplitude of the input of the ADC relative to the amplitude of the output of the charge amplifier.

19. The non-transitory computer readable storage medium of claim 17, wherein determining the gain control state comprises:
transitioning from the first gain control state to the second gain control state when the output of the ADC is at or below a first threshold;
remaining in the first gain control state when the output of the ADC is above the first threshold;
transitioning from the second gain control state to the first gain control state when the output of the ADC is at or above a second threshold; and
remaining in the second gain control state when the output of the ADC is below the second threshold.

20. The non-transitory computer readable storage medium of claim 17, the method further comprising:
adjusting a coupling between the output of the ADC and a decimation filter according to the gain control state.

21. The non-transitory computer readable storage medium of claim 20, wherein adjusting the coupling between the output of the ADC and the decimation filter comprises:
coupling, in the first gain control state, the output of the ADC to the decimation filter via a first signal path, wherein the output of the ADC is equal to an input of the decimation filter; and
coupling, in the second gain control state, the output of the ADC to the decimation filter via a second signal path, wherein the second signal path is different than the first signal path and wherein the second signal path is configured to scale the output of the ADC to decrease the input of the decimation filter relative to the output of the ADC.
